(19) United States
(12) Patent Application Publication
(10) Pub. No.: US 2025/0329407 A1
(43) Pub. Date: Oct. 23, 2025

(54) Stuck-at-Fault Coverage Testing for Memory Devices

(71) Applicant: Google LLC, Mountain View, CA (US)

(72) Inventors: Vevekanenda Gonugunta, Bengaluru (IN); Ankit Garg, Bengaluru (IN); Ajaykumar Prajapati, Bellandur (IN)

(73) Assignee: Google LLC, Mountain View, CA (US)

(21) Appl. No.: 19/200,337

(22) Filed: May 6, 2025

Related U.S. Application Data
(60) Provisional application No. 63/800,280, filed on May 5, 2025.

(51) Int. Cl. G11C 29/56

(52) U.S. Cl. CPC G11C 29/56012; G11C 29/56004; G11C 29/56016

(57) ABSTRACT

This document describes systems and techniques for detecting stuck-at-fault (SAF) defects at input pins of a memory device. For example, a system includes a memory device to receive data and address inputs. A clock interface is configured to generate a memory clock signal according to a first clock signal received at a clock input. A logic interface is configured to provide the inputs to the memory device during a shift cycle according to a second clock signal received at a logic clock input. A test interface is configured to receive a system clock signal and to selectively adjust the first clock signal and the second clock signal to cause address signals presented to the address inputs and data signals presented to the data inputs to cause the memory device to capture the inputs from a previous shift cycle or a current shift cycle to enable identification of stuck-at-fault defects.

### CROSS-REFERENCE TO RELATED APPLICATION

This application claims the benefit of U.S. Provisional Patent Application Ser. No. 63/800,280 filed on May 5, 2025, the disclosure of which is incorporated by reference herein in its entirety.

### SUMMARY

This document describes systems and techniques for detecting stuck-at-fault (SAF) defects at input pins of a memory device. Extended read and write intervals used by some memory devices may conceal when SAF defects prevent values at input pins from switching in response to inputs applied to the memory devices. Including a test interface between a clock source and both a clock interface and a logic interface that provide inputs to the memory device may change whether the memory device latches values presented by the logic interface to the memory device from a previous shift cycle or a next shift cycle. Selectively latching the values from a previous shift cycle or a next shift cycle may enable detection of SAF defects at the input pins of the memory device.

For example, a system includes a memory device to receive inputs including data and address inputs according to a memory clock signal. A clock interface is configured to generate the memory clock signal according to a first clock signal received at a clock input. A logic interface is configured to provide the inputs to the memory device during a shift cycle according to a second clock signal received at a logic clock input. A test interface is configured to receive a system clock signal and to selectively adjust the first clock signal and the second clock signal to adjust the memory clock signal and presentation of address signals provided to the address inputs and data signals provided to the data inputs. This adjustment can cause the memory device to capture the inputs from a previous shift cycle or from a current shift cycle to enable identification of stuck-at-fault defects in one or more of the inputs.

This Summary is provided to introduce systems and techniques for including a test interface to selectively determine values presented to a memory device to enable identification of SAF defects, as further described below in the Detailed Description and disclosed in the Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques for including a test interface to selectively determine values presented to a memory device to enable identification of SAF defects are described in this document with reference to the Drawings. The same numbers are used throughout the drawings to reference like features and components.

FIG. 1 is a block diagram of an example system including a memory device and a test interface to determine potential SAF defects of the memory device;

FIGS. 2A, 2B, and 2C are example timing diagrams depicting signals presented to the memory device based on control of the test interface of FIG. 1;

FIGS. 3 and 4 are schematic diagrams of example systems including a test interface to identify potential SAF defects at the memory device; and

FIG. 5 is a flow diagram of an example method for incorporating a test interface to identify potential SAF defects into a system with a memory device.

### DETAILED DESCRIPTION

### Overview

Some memory devices, such as Level 2 (L2) cache memory devices, provide extended read and write intervals to allow for latency in address and data inputs being provided at input pins of the memory devices. For example, an L2 cache may have a setup cycle that supports latency settings of setup=1, hold=1, write=2, and read=2. In comparison, most other random-access memory (RAM) devices support latency settings of setup=1, hold=0, write=1, and read=1. A clock signal from a system clock may be provided to a clock interface that generates a clock signal at a reduced duty cycle that is provided to the L2 cache memory device to latch the inputs received at the L2 cache memory device. The inputs, such as the address and data inputs, provided to the L2 cache memory device may be provided by a logic interface that includes a number of flip-flops that receive the inputs. The flip-flops provide the inputs to the L2 cache memory device in response to another clock signal that initiates a shift cycle to transfer the received inputs to the L2 cache memory device.

In testing a memory device such as an L2 cache memory device, an automatic test pattern generator (ATPG) may be used to generate a test pattern that is applied to the L2 cache memory to determine if the L2 cache memory correctly stores and generates data provided to the L2 cache memory device. Unfortunately, because the L2 cache memory device holds values presented at the address and data input pins for two clock cycles, holding the input values may conceal stuck-at-fault (SAF) defects at particular input pins that manifest when the values do not switch as anticipated.

To detect SAF defects, address and data inputs to the L2 cache memory device may be masked to prevent switching of the outputs from the flip-flops of the logic interface. However, masking the inputs to the L2 cache memory device requires interposing connections between the outputs of the flip-flops of the logic interface and the inputs of the L2 cache memory device. It would be desirable to be able to identify SAF defects without interposing connections between the logic interface and the L2 cache memory device.

This document describes systems and techniques for detecting stuck-at-fault (SAF) defects at input pins of a memory device without relying on such interposed connections. For example, a system includes a memory device to receive inputs including data and address inputs according to a memory clock signal. A clock interface is configured to generate the memory clock signal according to a first clock signal received at a clock input thereof. A logic interface is configured to provide the inputs to the memory device during a shift cycle according to a second clock signal received at a logic clock input of the logic interface. A test interface is configured to receive a system clock signal and to selectively adjust the first clock signal and the second clock signal. This adjustment of the first and second clock signals can adjust the memory clock signal and presentation of address signals provided to the address inputs and data signals provided to the data inputs to cause the memory device to capture the inputs from a previous shift cycle or from a current shift cycle to enable identification of stuck-at-fault defects in one or more of the inputs.

### Example Test Interface Environment

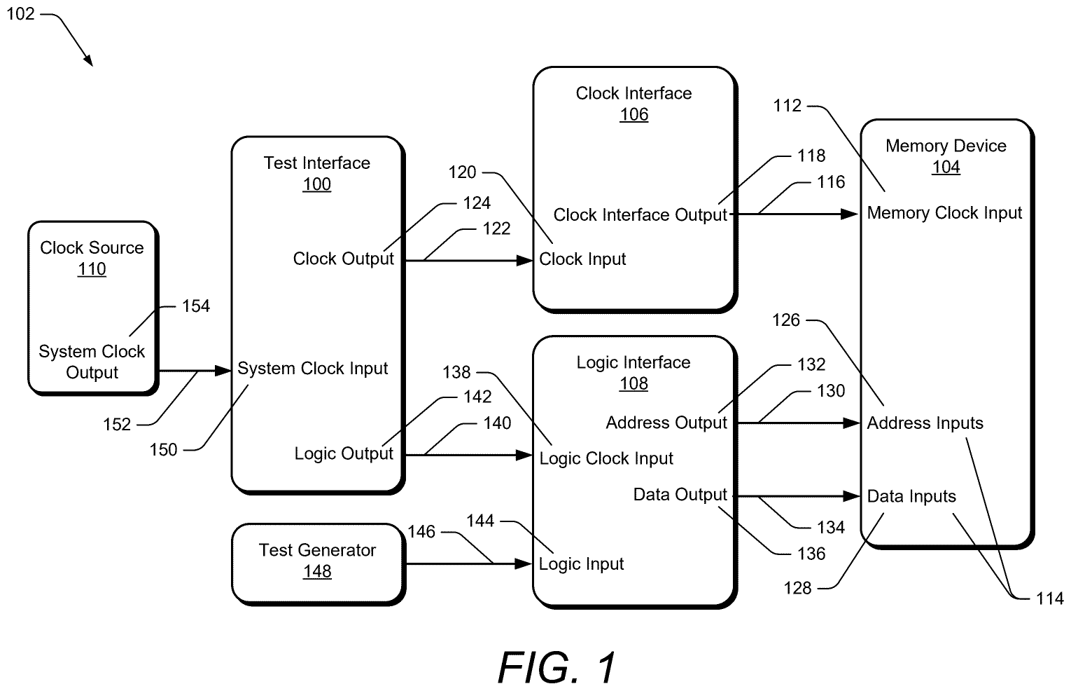

FIG. 1 shows an example test interface 100 that is included in a system 102 that includes a memory device 104, a clock interface 106, a logic interface 108, and a clock source 110. The memory device 104 may include or realize an L2 cache memory device or other two-cycle memory device, as further described below. The memory device 104 includes a memory clock input 112 that is used to latch inputs 114, as described further below. The memory clock input 112 receives a memory clock signal 116 that is generated by a clock interface output 118 of the clock interface 106. The clock interface 106 may include a stretch clock circuit that generates the memory clock signal 116 at a reduced duty cycle as compared to a clock input 120 of the clock interface 106. The clock input 120 receives a first clock signal 122 that is provided by a clock output 124 of the test interface 100, as described further below.

The system 102 can be realized with, for example, any suitable computing or other electronic device. Examples of the system 102 include a mobile electronic device or mobile device, mobile communication device, modem, cellular or mobile phone, mobile station, gaming device, navigation device, media or entertainment device (e.g., a media streamer or gaming controller), laptop computer, desktop computer, tablet computer, smart appliance, vehicle-based electronic system, wearable computing device (e.g., clothing, watch, or virtual reality glasses), Internet of Things (IoTs) device, sensor, stock management device, electronic portion of a machine or piece of equipment (e.g., a vehicle or robot), memory storage device (e.g., a solid-state drive (SSD)), server computer or portion thereof (e.g., a server blade or rack or another part of a datacenter), and so forth.

The inputs 114 received by the memory device 104 may include address inputs 126 and data inputs 128 that provide address information and data for the inputs 114, respectively. It will be appreciated that each of the address inputs 126 and data inputs 128 represents multiple-bit inputs. The address inputs 126 receive address signals 130 from an address output 132 of the logic interface 108. The data inputs 128 receive data signals 134 from a data output 136 of the logic interface 108. As described further below, the logic interface 108 may include a flip-flop for each of the bits of the address bits and data bits presented at the address output 132 and the data output 136, respectively. The logic interface 108 includes a logic clock input 138 that receives a second clock signal 140 from a logic output 142 of the test interface 100. The logic interface 108 also includes a multiple-bit logic input 144 that receives address and data signals 146 that, again for visual simplicity, are represented as a single input.

It will be appreciated that operation of the logic interface 108 is comparable to that of other logic interfaces in latching address and data signals 146 received at the logic input 144 and presenting such signals to the memory device 104, except for how the test interface 100 may control shift cycles of the logic interface 108, as further described below.

When the system 102 is in operation, the address and data signals 146 may be provided by a processor, memory, or other devices (not shown). For purposes of this description, however, the address and data signals 146 may be provided by a test generation system 148 or test generator 148. The test generation system 148 may employ automatic test pattern generation (ATPG) techniques to generate the address and data signals 146 that include known values. Whether outputs (not shown in FIG. 1) of the memory device 104 correspond to the values included in the address and data signals 146 presented to the address inputs 126 and the data inputs 128 may determine whether one or more of the input pins to the memory device 104 exhibit SAF defects.

The test interface 100 includes a system clock input 150 that receives a system clock signal 152 from a system clock output 154 of the clock source 110. The test interface 100, as described below, generates the first clock signal 122 at the clock output 124 and the second clock signal 140 at the logic output 142. In other approaches, a system clock signal 152 generated at a system clock output 154 of a clock source 110 is presented to a clock interface 106 and to a logic interface 108 without an intervening test interface. However, in example described implementations, the test interface 100 is configured to receive the system clock signal 152 and to selectively adjust the first clock signal 122 presented at the clock input 120 of the clock interface 106 and selectively adjust the second clock signal 140 presented at the logic input 144 of the logic interface 108. These two clock adjustments operate to adjust a presentation timing of the address signals 130 and the data signals 134 as presented at the address inputs 126 and the data inputs 128, respectively, of the memory device 104. The test interface 100 may thereby cause the memory device 104 to capture the inputs 114 from a previous shift cycle or from a current shift cycle to enable identification of SAF defects in one or more of the inputs 114.

In example operations, the circuitry can cause certain conditions to occur to facilitate the SAF testing. Here, the circuitry can include the test interface 100 interoperating with the logic interface 108 and/or the clock interface 106 to provide the inputs 114 to the memory device 104 to detect potential SAF. In some cases, during pattern generation and the application thereof to the memory device under test, the circuitry causes only one of two mutually exclusive conditions to be active. First, the interface logic data is held valid from the last shift cycle through the capture cycle, with the memory device capturing the data at the capture cycle. Second, the memory logic data is held valid from the last shift cycle through the capture cycle, with the interface logic capturing the data at the capture cycle. Other implementations, however, may alternatively be implemented.

### Example Operations of the Test Interface

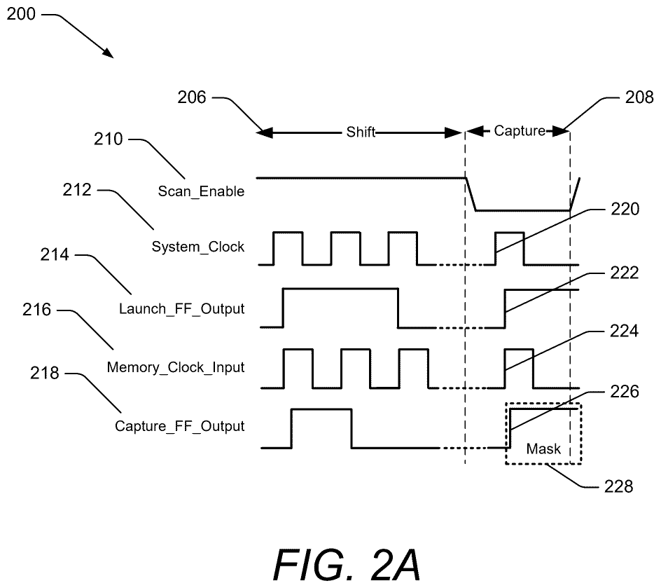

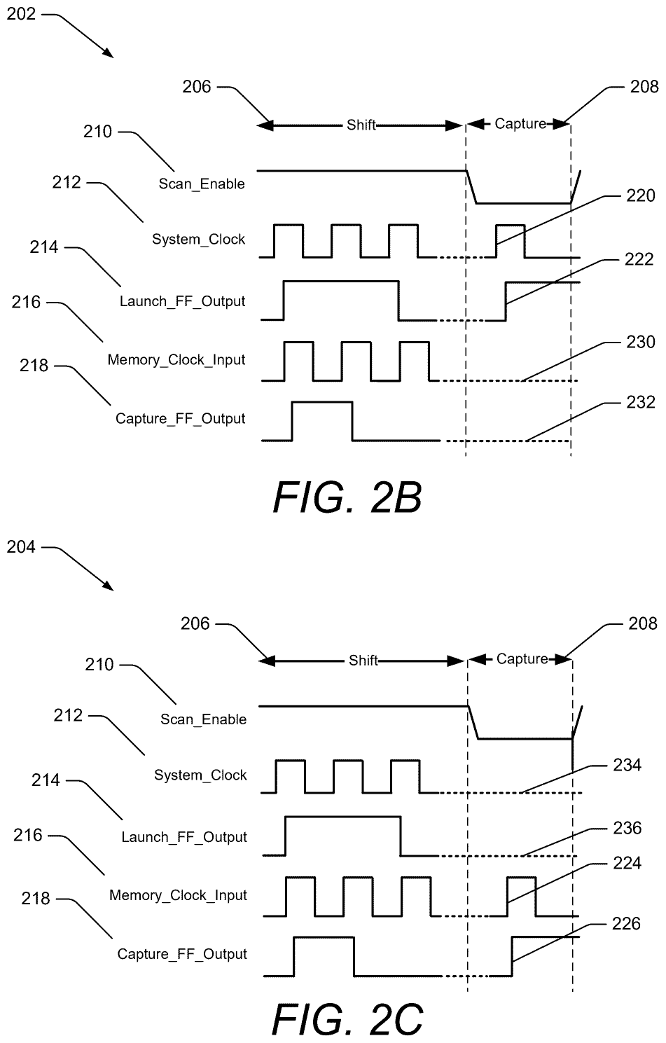

FIGS. 2A, 2B, and 2C are timing diagrams 200, 202, and 204, respectively, that represent how the test interface 100 included in the system 102 may control inputs presented at input pins of the memory device 104 of FIG. 1 to detect potential SAF defects. For example, the timing diagram 200 of FIG. 2A shows an example in which the test interface 100 of FIG. 1 is inactive. The timing diagram 200 includes a shift cycle 206 of signals that may be conveyed to the memory device 104 and a capture cycle 208 during which signals propagated during the shift cycle 206 may be captured by the memory device 104. A scan_enable signal 210 causes signals presented to the memory device 104 to be latched or read into the memory device 104. A system_clock signal 212, like the memory clock signal 116 generated by the clock interface output 118 of the clock interface 106, causes the signals to propagate during the shift cycle 206.

A launch_FF_output signal 214 represents outputs of flip-flops included in the logic interface 108 which may be presented as inputs to the memory device 104. A memory_clock_input signal 216, comparable to the memory clock signal 116 provided by the clock interface output 118 and generated by the clock interface 106, triggers the memory device 104 to read the inputs 114 presented by the launch_FF_output signal 214. As a result, the launch_FF_output signal 214 is captured as the capture_FF_output signal 218 that is stored in the memory device 104.

In testing the memory device 104 with signals provided by the test generator 148 (FIG. 1), it can be determined whether the output of the memory device 104 matches the patterns applied by the test generator 148. However, as previously described, a cache memory device, such as an L2 cache memory device, may have a setup cycle that supports latency settings of setup=1, hold=1, write=2, and read=2 in which the capture cycle is twice the length of a typical RAM capture cycle. As a result, multiple signals propagated during the shift cycle 206 may result in signals being presented to the memory device 104 switching during the capture cycle 208. Thus, if multiple signals may be presented to the memory device 104, it may be difficult to accurately test the memory device 104 to determine if any SAF defects may affect the inputs to the memory device 104.

For example, a rising edge 220 of the system_clock signal 212 during the capture cycle 208 may cause a value of a last shift cycle 222 represented in the launch_FF_output signal 214 to be latched into the memory device 104 based on a rising edge 224 of the memory_clock_input signal 216. However, during the double-length read/write cycle 200 following the rising edge 224 of the memory_clock_input signal 216, the capture_FF_output signal 218 may present values of a next shift cycle 226 represented in the launch_FF_output signal 214 to be latched into the memory device 104. In other approaches, to prevent the values of a next shift cycle 226 from being latched into the memory device 104, a mask 228 may be applied to block the capture_FF_output signal 218 to ensure that the value of a last shift cycle 222 is read into the memory device 104 for verification. However, masking the capture_FF_output signal 218 involves introducing an interface or device between the logic interface 108 and the memory device 104 that potentially introduces complexity, signal loss, or other undesirable effects in the system 102 once testing is no longer required.

In contrast, for example described implementations, without interposing masking between the logic interface 108 and the memory device 104, the test interface 100 provides for presenting to the memory device 104 either the signals from a last shift cycle or a next shift cycle. In other words, the test interface 100 causes the output of the logic interface 108 from the last shift cycle to be maintained through the capture cycle and captured during the capture cycle 208. Alternatively, the test interface 100 suppresses the output of the logic interface 108 from the last shift cycle, causing the memory device 104 to capture the output of the logic interface 108 from the next shift cycle during the capture cycle 208. These two cases are illustrated in the timing diagrams 202 and 204 of FIGS. 2B and 2C, respectively.

Referring to FIG. 2B, the timing diagram 202 illustrates a case in which the test interface 100 is configured to cause the memory device 104 to capture the output of the last shift cycle during the capture cycle 208. In contrast to the timing diagram 200 of FIG. 2A, the test interface 100 results in the memory_clock_input signal 216 having a suppressed output 230 which also results in the capture_FF_output signal 218 having a suppressed output 232. Thus, the data represented in the launch_FF_output signal 214 is latched into the memory device 104 based on the rising edge 224 of the memory_clock_input signal 216. Because the capture_FF_output signal 218 is suppressed, the output of the last shift cycle is latched into the memory device.

By contrast, referring to FIG. 2C, the timing diagram 204 illustrates a case in which the test interface 100 is configured to cause the memory device 104 to capture the output of the next shift cycle during the capture cycle 208. Thus, the test interface 100 results in the system_clock signal 212 having a suppressed output 234, causing the launch_FF_output signal 214 to also have a suppressed output 236. However, the rising edge 224 of the memory_clock_input signal 216 causes the capture_FF_output signal 218 to be presented to the memory device 104 to be captured by the memory device 104. Thus, the test interface 100 selectively controls whether the output of the last shift cycle or the next shift cycle is latched by the memory device 104 without having to apply a mask to the output of the logic interface 108, as in the example of the mask 228 of FIG. 2A.

### Example Implementations of the Test Interface

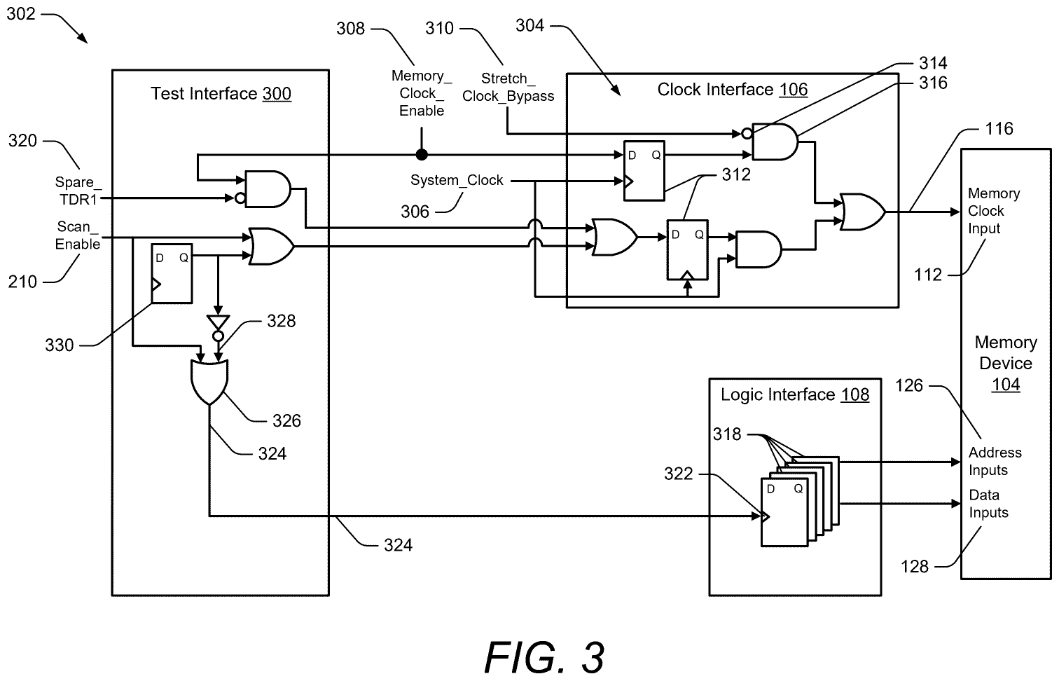

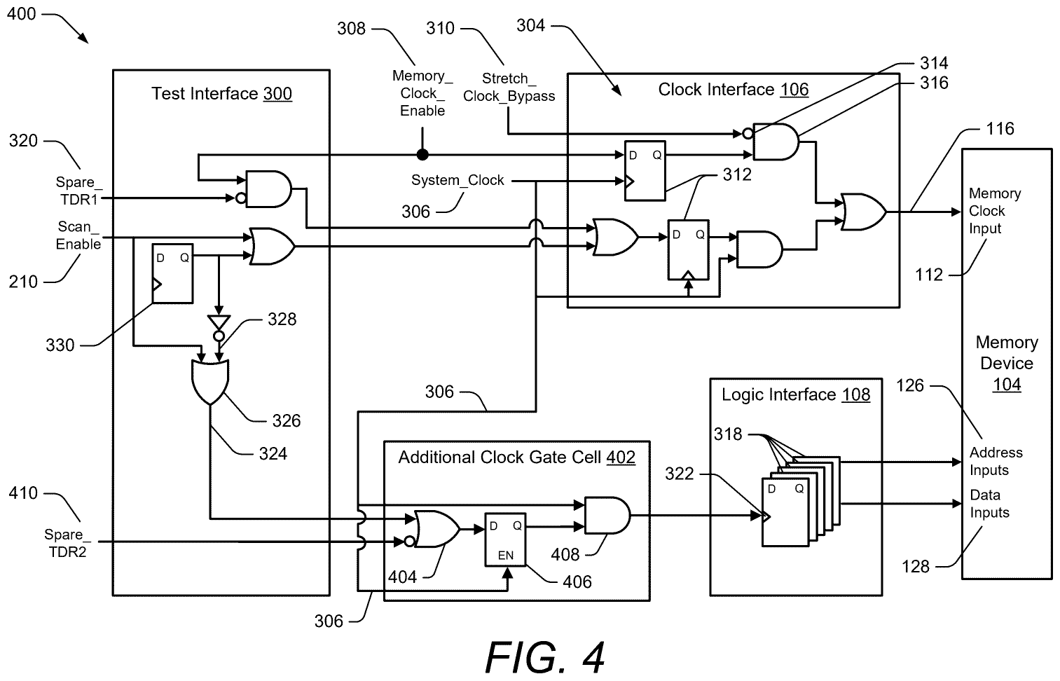

FIGS. 3 and 4 illustrate implementations of a test interface 300 between the clock source 110 and the clock interface 106 and/or the logic interface 108 to control whether the data of the last shift cycle or the next shift cycle is applied to and latched by the memory device 104. In aspects, the test interface 300 controls from which shift cycle data is presented to the memory device 104 by controlling clock signals presented to the logic interface 108.

In aspects, the clock interface 106 of the system 302 includes stretch clock circuitry 304. The stretch clock circuitry 304 receives a system_clock signal 306 generated by a clock source (not shown), a memory_clock_enable signal 308, and a stretch_clock_bypass signal 310. When receiving the system_clock signal 306 and the memory_clock_enable signal 308, the stretch clock circuitry 304 of the clock interface 106 causes the flip-flops 312 to generate a reduced duty cycle clock signal that is presented as the memory clock signal 116 to the memory clock input 112 of the memory device 104 unless the stretch_clock_bypass signal 310 presented to an inverted input 314 of an AND gate 316 bypasses the stretch clock circuitry 304.

As depicted in FIGS. 3 and 4, with the test interface 300 disabled (or in a system without a test interface 300), the system clock signal 306 is also presented to flip-flops 318 of the logic interface 108 to trigger the flip-flops 318 and thereby control shift cycles of the logic interface 108. Responsive to the system clock signal 306, the flip-flops 318 propagate input signals from a test generator 148 (FIG. 1) or other source of inputs (not shown) to the address inputs 126 and data inputs 128 of the memory device 104.

By contrast, with the test interface 300 enabled, whether signals from a last shift cycle or current shift cycle are presented to the memory device 104 may be controlled by inputs to the test interface 300, including the scan_enable signal 210 and a spare_TDR1 signal 320, and by the stretch_clock_bypass signal 310 applied to the stretch clock logic 304 of the clock interface 106. As a result of the logic included in the test interface 300, when the scan_enable signal 210 is at a low value, the data from the last shift cycle is held valid through the capture cycle at the memory device 104, as depicted in FIG. 2B. However, when the scan_enable signal 210 is at a high value, and the stretch_clock_bypass signal 310 and the spare_TDR1 signal 320 are also set to high values, the memory device 104 captures data currently presented at the memory device 104, as depicted in FIG. 2C. Thus, without applying masking to the address inputs 126 or the data inputs 128 to the memory device 104, the memory device 104 either reads inputs from a last shift cycle or a next shift cycle. SAF defects at input pins to the memory device 104 may therefore be identified without introducing data lines or circuitry between the logic interface 108 and the memory device 104. Then, when the memory device 104 has been tested, the test interface 300 may be disabled without affecting subsequent operations of the system 302.

It should be noted that, in the system 302, the flip-flops 318 of the logic interface 108 include clock gates at their enable pins 322 that receive an enable signal 324. The enable signal 324 is produced from an OR gate 326 that combines an inverted output 328 of a flip-flop 330 and the scan_enable signal 210. However, if the enable pins 322 do not include clock gates, some additional circuitry may be implemented.

Referring to FIG. 4, a system 400 is similar to the system 302 of FIG. 3 but with the inclusion of an additional clock gate cell 402. The additional clock gate cell 402 may include an OR gate 404, an additional flip-flop 406, and an additional AND gate 408. The OR gate 404 receives an inverted value of a spare_TDR2 signal 410 and the enable signal 324 from the OR gate 326. The flip-flop 406 receives an output of the OR gate 404 and is clocked by the system_clock signal 306. An output of the flip-flop 406 is combined with the system_clock signal 306 at the AND gate 408 to provide a clock gate signal for the flip-flops 318 of the logic interface 108. In this configuration, when the scan_enable signal 210 is at a low value, the data from the last shift cycle is held valid through the capture cycle at the memory device 104, as depicted in FIG. 2B. However, when the scan_enable signal 210 is at a high value, and the stretch_clock_bypass signal 310, the spare_TDR1 signal 320, and the spare_TDR2_signal 410 are also set to high values, the memory device 104 captures data currently presented at the memory device 104, as depicted in FIG. 2C.

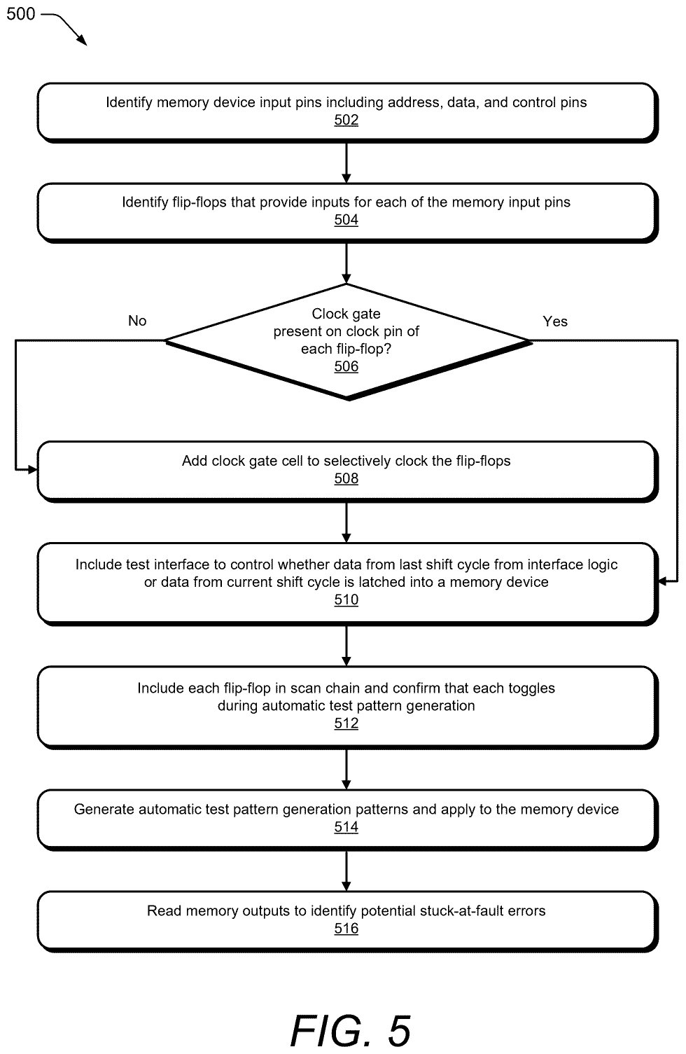

FIG. 5 is a flow diagram of an example process 500 for incorporating a test interface to identify potential SAF defects, such as the test interface 100 of FIG. 1 or the test interface 300 of FIGS. 3 and 4, into a system with a memory device. At a block 502, input pins of a memory device, including address, data, and control pins, are identified. At a block 504, flip-flops that provide inputs for each of the memory input pins are identified. At a block 506, it is determined if each of the flip-flops that provide inputs to each of the memory input pins includes a clock gate, as described with reference to FIG. 4. If it is determined at the block 506 that each of the flip-flops does not include a clock gate, at a block 508, additional clock gate logic is added to clock the flip-flops, as described with reference to FIG. 4.

At a block 510, a test interface is included to control whether data from a last shift cycle from interface logic or data from a current shift cycle is latched into a memory device as previously described with reference to FIGS. 2B, 2C, and 3. At a block 512, each of the flip-flops is included in a scan chain to confirm that each of the flip-flops toggles during automatic test pattern generation (ATPG). At a block 514, automatic test pattern generation patterns are generated and applied to the memory device. At a block 516, outputs of the memory device are read to identify potential stuck-at-fault (SAF) errors.

Aspects of these methods may be implemented in, for example, hardware (e.g., fixed logic circuitry, a controller, a finite state machine, or a processor in conjunction with a memory), firmware, software, or some combination thereof. The methods may be realized to produce one or more of the apparatuses or components shown in FIGS. 1, 3, and 4, which components may be further divided, combined, and so on or to produce one or more of the timing diagrams of FIGS. 2B and 2C. The devices and components of these figures generally represent hardware, such as electronic devices, PCBs, packaged modules, IC chips, components, or circuits; firmware; software; or a combination thereof. Thus, these figures illustrate some of the many possible systems or apparatuses capable of being produced using the described methods.

For the methods described herein and the associated flow chart(s) and/or flow diagram(s), the orders in which operations are shown and/or described are not intended to be construed as a limitation. Instead, any number or combination of the described method operations can be combined in any order to implement a given method or an alternative method, including by combining operations from different ones of the flow chart(s) and flow diagram(s) and the earlier-described schemes and techniques into one or more methods. Operations may also be omitted from or added to the described methods. Further, described operations can be implemented in fully or partially overlapping manners.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although implementations of systems and techniques for including a test interface to selectively determine values presented to a memory device to enable identification of SAF defects have been described in language specific to certain features and/or methods, the subject of the appended claims is not necessarily limited to the specific features or methods described. Rather, the specific features and methods are disclosed as example implementations of systems and techniques for including a test interface to selectively determine values presented to a memory device to enable identification of SAF defects.

What is claimed is:

1. A system comprising:
a memory device to receive inputs including data and address inputs according to a memory clock signal;
a clock interface configured to generate the memory clock signal according to a first clock signal received at a clock input;
a logic interface configured to provide the inputs to the memory device during a shift cycle according to a second clock signal received at a logic clock input; and
a test interface configured to receive a system clock signal and to selectively adjust the first clock signal and the second clock signal to adjust the memory clock signal and presentation of address signals presented to the address inputs and data signals presented to the data inputs to cause the memory device to capture the inputs from a previous shift cycle or from a current shift cycle to enable identification of stuck-at-fault defects in one or more of the inputs.

2. The system of claim 1, wherein the test interface is configured to adjust at least one of the first clock signal and the second clock signal applied to the logic clock input of the interface logic to cause the logic interface to maintain the inputs from the previous shift cycle or the current shift cycle during a capture cycle of the memory device triggered by the first clock signal applied to the clock input of the clock interface.

3. The system of claim 2, the wherein the test interface is configured to cause the logic interface to maintain the inputs from the previous shift cycle or the current shift cycle during the capture cycle of the memory device triggered by the first clock signal applied to the clock input of the clock interface without modifying operation of either the clock interface or the logic interface.

4. The system of claim 1, wherein the test interface includes logic circuitry interposed between a clock source that generates the system clock signal and the clock input of the clock interface and the logic clock input of the logic interface.

5. The system of claim 1, wherein the logic interface includes a plurality of flip-flops configured to trigger a transition from a previous shift cycle to the current shift cycle in response the second clock signal received at the logic clock input.

6. The system of claim 5, further comprising:
an additional clock gate cell to provide clock inputs to the plurality of flip-flops.

7. The system of claim 1, wherein the clock interface includes a stretch clock that receives the first clock signal at the clock input and generates the memory clock signal at a reduced duty cycle.

8. The system of claim 1, wherein the memory device comprises a cache memory device.

9. The system of claim 8, wherein the cache memory device includes a level 2 (L2) cache memory device having an extended read or write interval.

10. The system of claim 1, wherein the system comprises a mobile device.
